(19) United States
(12) Patent Application Publication
(10) Pub. No.: US 2023/0350600 A1
(43) Pub. Date: Nov. 2, 2023

(54) DISPLAY METHOD OF INTELLIGENT MEMORY AND STRUCTURE THEREOF

(71) Applicant: TEAM GROUP INC., NEW TAIPEI CITY (TW)

(72) Inventors: CHIN FENG CHANG, NEW TAIPEI CITY (TW); HSI LIN KUO, NEW TAIPEI CITY (TW)

(21) Appl. No.: 17/811,601

(22) Filed: Jul. 11, 2022

(30) Foreign Application Priority Data
Apr. 28, 2022 (TW) 111116208

(51) Int. Cl. G06F 3/06; G10K 9/12; G08B 21/18; G08B 5/36

(52) U.S. Cl. CPC G06F 3/0653; G10K 9/12; G08B 21/182; G08B 5/36; G06F 3/0604; G06F 3/0679

(57) ABSTRACT

The present invention provides a display method and structure of an intelligent memory, which is a temperature detection method and structure, which is used in a memory device, of which the memory device includes a substrate, a thermal sensor, a plurality of memory chips, a micro-control unit, and a notification module. The steps include generating at least one temperature data according to the temperature of the plurality of memory chips sensed by the thermal sensor, transmitting the at least one temperature data to the micro-control unit, and the micro-control unit determining whether the at least one temperature data exceeds a first threshold, When at least one temperature data exceeds the first threshold, the micro-control unit transmits a first control signal to a notification module, which can further be used for the method and structure for displaying real-time information.

### FIELD OF THE INVENTION

The invention relates to a display method of a memory and structure thereof, particularly a display method of an intelligent memory and structure thereof.

### BACKGROUND OF THE INVENTION

Memory is an electronic device for storing data, which is currently widely used in products that need to store data, such as computers, mobile phones, and game software.

Solid state drive is a storage hard drive made of integrated circuit. Since the first solid state drive was released in 1989, it has also been widely used in various hard disk drives with the advantage of faster speed and low power consumption.

Inter-integrated circuit (VC) is a serial communication bus that uses two communication lines to transmit information between integrated circuits (IC).

To monitor the temperature of the internal parts of the computer, yet not to increase too much volume, it associates the combination of thermal sensor and electronic erasable programmable read-only memory (EEPROM) that can frequently erase data and write new data by a specific voltage. EEPROM is also frequently used inside DDR memory.

Nowadays, computers are widespread in various places, including home personal computers, portable notebook computers, computers used by personnel in companies and schools, and computers for performing process steps in industrial manufacturing or laboratory operations, and computers for collecting data.

With the widespread of the computer and the associated products, users began to use computers for various entertainment and competitions, and pursuing computer performance, self-assembly, and increasing computer performance, and memory space. Except the performance, computer shells forward to the direction of non-single color and begin to have a pattern or even transparent design. With the lighting settings, we can clearly see the internal structure, including whether the fans and other parts are running; using the RGB lighting program, the computer can be operated with the light emission under specific colors according to the user's favorite, toward the personalized design.

The irradiation feature of the computer or related devices are widely applied on the e-sports computer equipment, but the function is limited to decorate the computer and notify that the devices are operating.

When used in the factory, the equipment usually has the notification function or equipped with additional sensors so that the equipment radiates specific colors or ring the buzzer as the alarm and let user immediately stop the operation and repair the equipment; or it notifies personnel to conduct emergency evacuation to reduce casualties from accidents in when abnormal conditions such as gas leakage occur. Computers that enable normal operation of equipment usually do not add additional lights or buzzers to reveal the state of the computer itself, such as the internal temperature of computer; to confirming the status, personnel needs to access the computer program to read the temperature of the parts. When the factory computer is running, the screen will display the manufacturing status, or the running page that needs to be controlled by personnel, yet it won't timely display the computer status.

Therefore, when the temperature of computer parts is abnormal, it is difficult for on-site personnel to find out immediately; only when the abnormal temperature causes the computer unable to perform normally, operator then realizes the abnormality of the cooling system or other reasons that cause the unacceptable high temperature of the computer.

In addition, if the internal computer in the factory can have a method of warning the on-site personnel before the abnormal temperature of the memory causes the overheating, it can reduce the occurrence of memory damage caused by the overheating.

The invention provides an intelligent memory, which is aimed at solving the conventional understanding that the memory temperature needs to pass through the CPU that increase the load of CPU, and there is no other structure or method designed to display the state of the memory.

### SUMMARY

An objective of the present invention is to provide a display method and structure of an intelligent memory, which can automatically detect the temperature of the memory device according to the thermal sensor inside the memory to achieve the goal of automatic temperature detection.

In order to achieve the above objectives, the present invention provides a display method and structure of an intelligent memory with temperature monitoring, which is used for a memory device, wherein the memory device comprising a substrate, a thermal sensor, a plurality of memory chips, a micro-control unit and a notification module, and the thermal sensor, memory chips, micro-control unit and notification module are equipped on the substrate, wherein the steps of the intelligent memory temperature monitoring method comprising: generating at least one temperature data according to the temperature of the memory chips detected by the thermal sensor; determining whether the at least one temperature data is not less than a first threshold when the at least one temperature data is transmitted to the micro-control unit; transmitting a first control signal to a notification module from the micro-control unit when the at least one temperature is not less than the first threshold.

The invention provides an embodiment, wherein in said step of transmitting a first control signal to a notification module from the micro-control unit when the at least one temperature is not less than the first threshold, comparing the at least one temperature and a second threshold by the micro-control unit, and transmitting the first control signal to the notification module by the micro-control unit if the at least one temperature is less than a second threshold.

The invention provides an embodiment, wherein in said step of when said step of transmitting a first control signal to a notification module by the micro-control unit when the at least one temperature is not less than the first threshold, when the at least one temperature is not less than the second threshold, further comparing the at least one temperature data and a third threshold by the micro-control unit, and transmitting a second control signal to the notification module by the micro-control unit if the at least one temperature data is not less than a third threshold, or transmitting a third control signal to the notification module by the micro-control unit if the at least one temperature data is less than a third threshold.

The invention provides an embodiment, wherein the notification module comprising a first light-emitting device; and the first light-emitting device emits light with the first corresponding color when the notification module receives the first control signal.

The invention provides an embodiment, in which the notification module comprising a second light-emitting device and a third light-emitting device, and the second light-emitting device emits light with the second corresponding color when the notification module receives the second control signal, and the third light-emitting device emits light with the third corresponding color when the notification module receives the third control signal.

The invention provides an embodiment, in which the notification module comprising a buzzer, and the buzzer generates a first sound when the notification module receives the first control signal; the buzzer generates a second sound when the notification module receives the second control signal; and the buzzer generates a third sound when the notification module receives the third control signal.

The invention provides an embodiment, in which the memory device is a volatile memory, a non-volatile memory, or a solid state drive.

The invention provides an embodiment, in which the memory device is electrically connected to a motherboard, and a CPU transmits a control command to the memory device through the motherboard.

Another objective of the invention is to provide a display method and structure of an intelligent memory, using the micro-control unit to determine the temperature data and the threshold of the body; if the temperature data exceeds the threshold, the micro-control unit transmits control signals to the notification module, making the notification module able to immediately notify the on-site personnel.

For the previously mentioned goal, the invention provides a structure of an intelligent memory with temperature monitoring. The intelligent memory comprising: a substrate, which is equipped with a micro-control unit and a plurality of memory chips, wherein the micro-control unit is electrically connected to the memory chips; a thermal sensor, which is deposited on the substrate and is electrically connected to the micro-control unit to detect one of the memory chips; and a notification module, which is deposited on the substrate and is electrically connected to the micro-control unit, wherein the micro-control unit receives at least one temperature from the thermal sensor; and the micro-control unit transmits a first control signal to the notification module when the at least one temperature is not less than a first threshold.

The invention provides an embodiment, wherein in said step of transmitting a first control signal to a notification module by the micro-control unit when the at least one temperature is not less than the first threshold, the micro-control unit determines that whether the at least one temperature is less than a second threshold, and if so, the micro-control unit transmits the first control signal to the notification module.

The invention provides an embodiment, wherein in said step of the micro-control unit transmits a first control signal to the notification module when the at least one temperature is not less than a first threshold, further comparing the at least one temperature and a third threshold by the micro-control unit when the at least one temperature is not less than the second threshold, and transmitting a second control signal to the notification module by the micro-control unit if the at least one temperature is not less than the third threshold, or the micro-control unit transmits a third control signal to the notification module by the micro-control unit if the at least one temperature is less than the third threshold.

The invention provides an embodiment, wherein the notification module comprising a first light-emitting device, and the light-emitting devices emit light with a first corresponding color when the notification module receives the first control signal.

The invention provides an embodiment, in which a second light-emitting device and a third light-emitting device; the light-emitting device emits light with a second corresponding color when the notification module receives the second control signal; and the light-emitting device emits light with a third corresponding color when the notification module receives the third control signal.

The invention provides an embodiment, in which the notification module comprising a buzzer, and the buzzer generates a first sound when the notification module receives the first control signal, and the buzzer generates a second sound when the notification module receives the second control signal, and the buzzer generates a third sound when the notification module receives the third control signal.

The invention provides an embodiment, in which the intelligent memory is a volatile memory, a non-volatile memory or a solid state drive.

The invention provides an embodiment, in which the intelligent memory is electrically connected to a motherboard, and a CPU unit transmits a control command to the memory device through the motherboard.

Also, another objective of the invention is to provide an intelligent memory, which can use the notification module of the intelligent memory for notification when communication software inputs a message.

For the previously mentioned goal, the invention provides a display method of an intelligent memory used for a memory device, wherein the memory device is electrically connected to a motherboard, the motherboard is electrically connected to a CPU, and the memory device comprising a substrate, a micro-control unit, and a notification module, and the micro-control unit and the notification module are equipped on the substrate, wherein the steps of the intelligent memory monitoring method comprising: sending a real-time signal to the motherboard via a server by an electronic device, wherein the motherboard receives the real-time signal by running a software by the CPU; transmitting a signal to the micro-control unit by the CPU; and transmitting a control signal by the micro-control unit to activate the notification module.

The invention provides an embodiment, in which the software is a real-time messaging software or a game software.

The invention provides an embodiment, in which the notification module comprising a first light-emitting device, a second light-emitting device, and a third light-emitting device, and the first light-emitting device, second light-emitting device and third light-emitting device emit light with a corresponding color when the notification module receives the control signal.

The invention provides an embodiment, in which the notification module comprising a buzzer, and the buzzer generates a corresponding sound when the notification module receives the control signal.

The invention provides an embodiment, in which the memory device is a volatile memory, a non-volatile memory, or a solid state drive.

The invention also provides a structure of an intelligent memory, which is electrically connected to a motherboard and the motherboard is electrically connected to a CPU. The intelligent memory comprising: a substrate, equipped with a micro-control unit; and a notification module, which is deposited on the substrate and is electrically connected to the micro-control unit; wherein an electronic device transmits a real-time signal to the motherboard via a server, and the motherboard receives the real-time signal by running a software by the CPU, and the CPU transmits a signal to the micro-control unit, and the micro-control unit transmits a control signal to activate the notification module.

The invention provides another embodiment, in which the software is a real-time communication software or a game software.

The invention provides another embodiment, in which the notification module comprising a first light-emitting device, a second light-emitting device, and a third light-emitting device, wherein the first light-emitting device, the second light-emitting device and the third light-emitting device emit lights with a corresponding color when the notification module receives the control signal.

The invention provides another embodiment, in which the notification module comprising a buzzer; and the buzzer generates a corresponding sound when the notification module receives the control signal.

The invention provides another embodiment, in which the intelligent memory is a volatile memory, a non-volatile memory, or a solid state drive.

### BRIEF DESCRIPTION OF THE FIGURES

FIG. 1 shows a flowchart of temperature detection of the intelligent memory in the first embodiment of the present invention;

FIG. 2 shows a block diagram of intelligent memory structure in the first embodiment of the present invention;

FIG. 3 shows a flowchart of temperature detection of the intelligent memory in the second embodiment of the present invention;

FIG. 4 shows a block diagram of intelligent memory structure in the second embodiment of the present invention;

FIG. 5 shows a flowchart of temperature detection of the intelligent memory in the third embodiment of the present invention;

FIG. 6 shows a block diagram of intelligent memory structure in the third embodiment of the present invention;

FIG. 7 shows a flowchart of temperature detection of the intelligent memory in the fourth embodiment of the present invention;

FIG. 8 shows a block diagram of intelligent memory structure in the fourth embodiment of the present invention;

FIG. 9 shows a flowchart of notification method of the intelligent memory in the fifth embodiment of the present invention;

FIG. 10 shows a block diagram of intelligent memory structure in the fifth embodiment of the present invention;

FIG. 11 shows a flowchart of notification method of the intelligent memory in the sixth embodiment of the present invention; and

FIG. 12 shows a block diagram of intelligent memory structure in the sixth embodiment of the present invention.

### DETAILED DESCRIPTION

Although the conventional memory has the design of a light-emitting structure, yet, it is only used for appearance changes, there is no self-monitoring system to monitor whether the memory temperature exceeding the threshold, making user unable to immediately sense the too-high-temperature state of the memory.

The invention provides an intelligent memory, the memory itself is equipped with the thermal sensor to sense the memory temperature, the sensed temperature is compared by the micro-control unit, and the corresponding control signal is sent to the notification module, which cooperates with the threshold, RGB color mixing setting of the light-emitting device and buzzer setting set by previous user by corresponding software. The computer CPU transmits the setting result as a signal to the micro-control unit of the memory through a signal line, or to the solid state drive controller through another signal line; then, the solid state drive controller transmits the signal to the micro-control unit of the solid state drive. The notification module makes the internal light-emitting device and the buzzer respond according to the corresponding control signal provided by the micro-control unit. Then, it achieves the effect of real-time notifying the user when the memory temperature is too high.

In the following articles, the invention will make detailed description by graphically illustrating different embodiments of the invention. However, the concepts of the invention can be embodied in many different forms and should not be limited to the exemplary embodiments set forth herein.

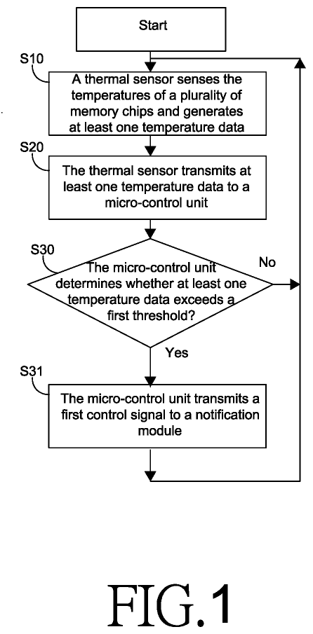

First, refer to FIG. 1, which is the flowchart of temperature detection of the intelligent memory in the first embodiment of the invention. As shown in the figure, the first embodiment of the temperature detection method of the intelligent memory of the invention proceeds as follows:

Step S10: At Thermal sensor 103 senses the temperatures of a plurality of memory chips 104 and generates at least one temperature data 1041;

Step S20: The thermal sensor 103 transmits at least one temperature data 1041 to a micro-control unit 102;

Step S30: The micro-control unit 102 determines whether at least one temperature data 1041 exceeds a first threshold 21, and if so, run step S31, otherwise, returns to step S10; and

Step S31: The micro-control unit 102 transmits a first control signal 211 to a notification module 105.

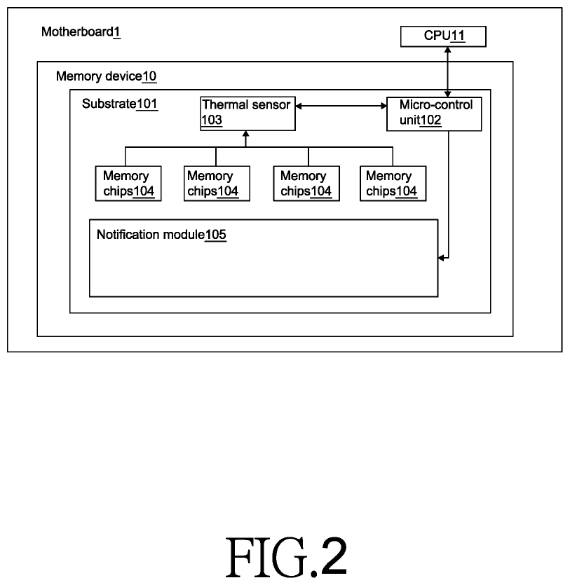

Referring to FIG. 2, which is the block diagram of intelligent memory structure in the first embodiment of the invention. As shown in the figure, the structure of the intelligent memory of the invention is used for a memory device 10; the memory device 10 includes a substrate 101, a thermal sensor 103, a plurality of memory chips 104, a micro-control unit 102 and a notification module 105, of which the thermal sensor 103, the memory chips 104, the micro-control unit 102 and the micro-control unit 102 are equipped on the substrate 101, the thermal sensor 103 is electrically connected to the memory chips 104, and the micro-control unit 102 is electrically connected to the thermal sensor 103 and the notification module 105.

Referring to FIG. 1 again, the steps of the intelligent memory temperature detection method in the first embodiment of the invention will be described in detail below. As shown in step S10, the thermal sensor 103 of a memory device 10 senses a plurality of memory chips 104 in the memory device 10, of which the thermal sensor 103 can select the temperature of one or more memory chips 104 from the plurality of memory chips 104 to generate at least one temperature data 1041; the memory device 10 can be a volatile memory, a non-volatile memory or a solid state drive.

As shown in step S20, the thermal sensor 103 will generate the at least one temperature data 1041 and transmit it to the micro-control unit 102.

As shown in step S30, the micro-control unit 103 compares the at least one temperature data 1041 with the first threshold 21 and determines whether the at least one temperature data 1041 exceeds the first threshold 21, and if so, run step S31, otherwise, go back to step S10, of which the first threshold 21 has been set by the user to start the corresponding program of the computer before the process starts, and the CPU 11 on the motherboard 1 transmits the setting result to the micro-control unit 103 by a signal line, or the CPU 11 transmits it to the solid state drive controller through the signal line; then, the solid state drive controller transmits the signal to the micro-control unit 103 of the solid state drive.

As shown in step S31, the micro-control unit 103 will transmit the first control signal 211 to the notification module 105.

The thermal sensor 103 is set in the memory device 10 in the first embodiment of the invention; the memory device 10 can sense the temperature of the memory device 10 itself, and transmit the temperature to the notification module 105 in a real-time manner to solve the conventional needs that the temperature of the memory can be detected by the sensor set in the computer, such as detecting the temperatures of volatile memory, non-volatile memory and solid state drive and the availability/health status.

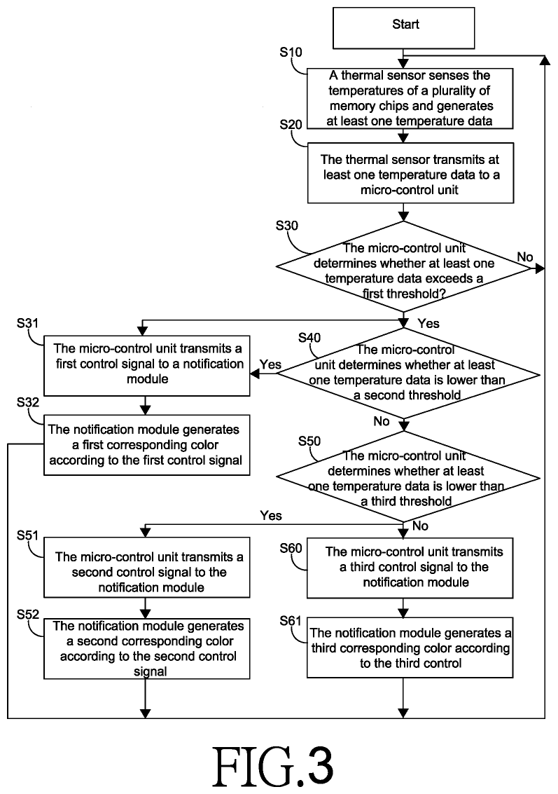

Continuing the above, refer to FIG. 3, which is the flowchart of temperature detection of the intelligent memory in the second embodiment of the invention, in which steps S10 to S20 are identical to the one in the previous embodiment and won't be iterated once again.

The steps of the second embodiment of the invention are as follows:
Step S30: The micro-control unit 102 determines whether at least one temperature data 1041 exceeds a first threshold 21, and if so, run step S31 and step S40, otherwise, returns to step S10;
Step S31: The micro-control unit 102 transmits a first control signal 211 to a notification module 105;
Step S32: The notification module 105 generates a first corresponding color 212 according to the first control signal 211;
Step S40: The micro-control unit 102 determines whether at least one temperature data 1041 is less than a second threshold 22, and if so, run step S31; if no, run step S50;
Step S50: The micro-control unit 102 determines whether at least one temperature data 1041 is less than a third threshold 23, and if so, run step S51; if no, run step S60;
Step S51: The micro-control unit 102 transmits a second control signal 221 to the notification module 105;
Step S52: The notification module 105 generates a second corresponding color 222 according to the second control signal 221;
Step S60: The micro-control unit 102 transmits a third control signal 231 to the notification module 105;
Step S61: The notification module 105 generates a third corresponding color 232 according to the third control signal 231.

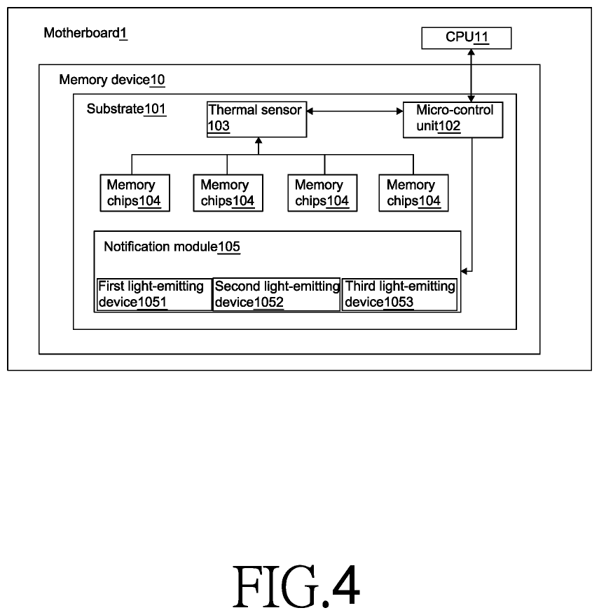

Referring to FIG. 4, which is the block diagram of intelligent memory structure in the second embodiment of the invention. As shown in the figure, the structure in the intelligent memory of the invention is used for the memory device 10; the memory device 10 includes the substrate 101, the thermal sensor 103, the memory chips 104, the micro-control unit 102 and the notification module 105, of which the thermal sensor 103, the memory chips 104, the micro-control unit 102 and the micro-control unit 102 is equipped on the substrate 101, the thermal sensor 103 is electrically connected to the memory chips 104, the micro-control unit 102 is electrically connected to the thermal sensor 103 and the notification module 105; the notification module 105 includes a first light-emitting device 1051, a second light-emitting device 1052, and a third light-emitting device 1053.

Referring to FIG. 3 again; the steps of the intelligent memory temperature detection method in the second embodiment of the invention are to be described in detail below. As shown in step S30, the micro-control unit 103 compares the at least one temperature data 1041 with the threshold 21 and determines whether the at least one temperature data 1041 exceeds the first threshold 21, and if so, run step S31 and step S40, otherwise, return to step S10.

Step S31 is identical to the previous embodiment and will not be iterated once again.

As shown in step S32, the notification module 105 comprising the first light-emitting device 1051, the second light-emitting device and the third light-emitting device 1053; the notification module 105 makes this first light-emitting device 1051 to emits light with a first corresponding color 212 according to the first control signal 211, of which the first corresponding color 212 has been set by the user by initiating a corresponding computer program before starting the process, and the CPU 11 transmits the setting result to the micro-control unit 103 through the signal line, or the CPU 11 transmits it to the solid state drive controller through a signal line, then, the solid state drive controller transmits it to the micro-control unit 103 of the solid state drive.

As shown in step S40, the micro-control unit 103 compares the at least one temperature data 1041 with a second threshold 22, and determines whether the at least one temperature data 1041 is less than the second threshold 22, and if so, run step S31, otherwise, run step S50, of which the second threshold 22 has been set by the user to start the corresponding program of the computer before the process starts, and the CPU 11 transmits the setting result to the micro-control unit 103 by a signal line, or the CPU 11 transmits it to the solid state drive controller through the signal line; then, the solid state drive controller transmits the signal to the micro-control unit 103 of the solid state drive.

As shown in step S50, the micro-control unit 103 compares the at least one temperature data 1041 with a third threshold 23, and determines whether the at least one temperature data 1041 is less than the third threshold 23, and if so, run step S51, otherwise, run step S53, of which the third threshold 23 has been set by the user to start the corresponding program of the computer before the process starts, and the CPU 11 transmits the setting result to the micro-control unit 103 by a signal line, or the CPU 11 transmits it to the solid state drive controller through the signal line; then, the solid state drive controller transmits the signal to the micro-control unit 103 of the solid state drive.

As shown in step S51, the micro-control unit 103 transmits a second control signal 221 to the notification module 105.

As shown in step S52, the notification module 105 emits light with a second corresponding color 222 according to the second control signal 221 and the second light-emitting device 1052, of which the second corresponding color 222 has been set by the user to start the corresponding program of the computer before the process starts, and the CPU 11 transmits the setting result to the micro-control unit 103 by a signal line, or the CPU 11 transmits it to the solid state drive controller through the signal line; then, the solid state drive controller transmits the signal to the micro-control unit 103 of the solid state drive.

As shown in step S60, the micro-control unit 103 will transmit a third control signal 231 to the notification module 105.

As shown in step S61, the notification module 105 makes the third light-emitting device 1053 emit light with a third corresponding color 232 according to the third control signal 231, of which the third corresponding color 232 has been set by the user to start the corresponding program of the computer before the process starts, and the CPU 11 transmits the setting result to the micro-control unit 103 by a signal line, or the CPU 11 transmits it to the solid state drive controller through the signal line; then, the solid state drive controller transmits the signal to the micro-control unit 103 of the solid state drive.

The thermal sensor 103 is equipped in the memory device 10 in the second embodiment of the invention; the memory device 10 can sense the temperature of the memory device 10 by itself, and detects the temperature of the memory device 10 in real-time manner through a notification module 105. The first light-emitting device 1051, second light-emitting device 1052 and third light-emitting device 1053 inside the notification module 105 will notify the user and solve the conventional needs of obtaining the temperatures through checking the status of computer parts; user thus can know the temperature status of the memory device 10 and determine whether to cool down and other processing in a real-time manner, which can solve the problem that user cannot immediately respond to the memory damage when the memory temperature is too high, such as detecting the temperatures of volatile memory, non-volatile memory and solid state drive and the temperatures, availability/health status.

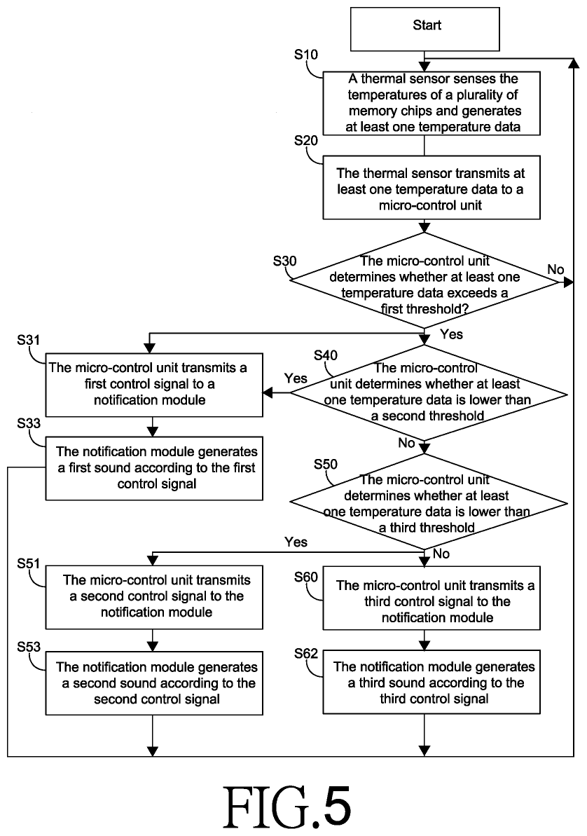

Continuing the above, please refer to FIG. 5, which is the flowchart of temperature detection of the intelligent memory in the third embodiment of the invention, of which steps S10 to S60, S31 and S51 are identical to the one in the second embodiment and won't be iterated once again.

The steps of the third embodiment of the invention are as follows:
Step S33: The notification module 105 generates a first sound 213 according to the first control signal 211;
Step S53: The notification module 105 generates a second sound 223 according to the second control signal 221;
Step S62: The notification module 105 generates a third sound 233 according to the third control signal 231.

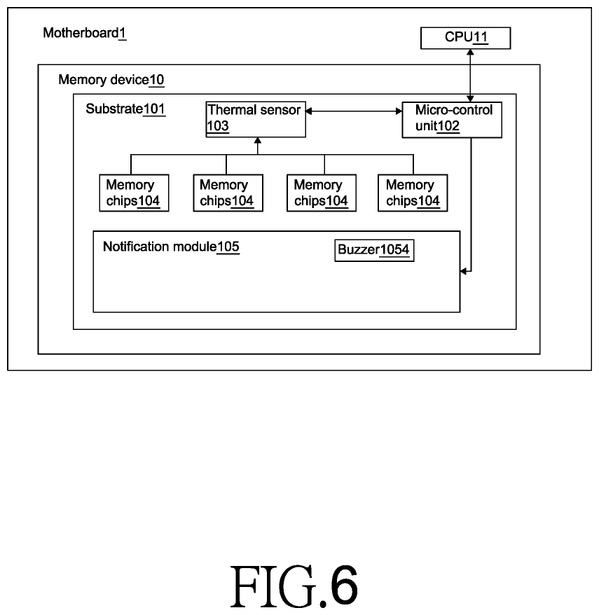

Referring to FIG. 6, which is the block diagram of intelligent memory structure in the third embodiment of the invention. As shown in the figure, the structure of the intelligent memory of the invention is used for the memory device 10; the memory device 10 includes the substrate 101, thermal sensor 103, memory chips 104, micro-control unit 102, and notification module 105, of which the thermal sensor 103, memory chips 104, micro-control unit 102, and micro-control unit 102 is equipped on the substrate 101; the thermal sensor 103 is electrically connected to the memory chips 104, and the micro-control unit 102 is electrically connected to the thermal sensor 103 and the notification module 105; the notification module 105 includes the buzzer 1052.

Referring to FIG. 5 again, the temperature detection method for intelligent memory in the third embodiment of the invention will be described in detail below. As shown in step S33, the notification module 105 includes a buzzer 1054, and the notification module 105 makes the buzzer 1054 to generate a first sound 213 according to the first control signal 211; of which the first sound 213 has been set by the user to start the corresponding program of the computer before the process starts, and the CPU 11 transmits the setting result to the micro-control unit 103 by a signal line, or the CPU 11 transmits it to the solid state drive controller through the signal line; then, the solid state drive controller transmits the signal to the micro-control unit 103 of the solid state drive.

As shown in step S53, the notification module 105 makes the buzzer 1054 generate a second sound 223 according to the second control signal 221, of which the second sound 223 has been set by the user to start the corresponding program of the computer before the process starts, and the CPU 11 transmits the setting result to the micro-control unit 103 by a signal line, or the CPU 11 transmits it to the solid state drive controller through the signal line; then, the solid state drive controller transmits the signal to the micro-control unit 103 of the solid state drive.

As shown in step S62, the notification module 105 makes the buzzer 1054 generate a third sound 233 according to the third control signal 231, of which the third sound 233 has been set by the user to start the corresponding program of the computer before the process starts, and the CPU 11 transmits the setting result to the micro-control unit 103 by a signal line, or the CPU 11 transmits it to the solid state drive controller through the signal line; then, the solid state drive controller transmits the signal to the micro-control unit 103 of the solid state drive.

The thermal sensor 103 is equipped in the memory device 10 in the third embodiment of the invention; the memory device 10 can sense the temperature of the memory device 10 by itself, and detect the temperature of the memory device 10 in a real-time manner through a notification module 105. The buzzer 1054 in the notification module 105 notifies the user and solve the conventional needs of obtaining the temperatures through checking the status of computer parts; user thus can know the temperature status of the memory device 10 and determine whether to cool down and other processing in a real-time manner, which can solve the problem that user cannot immediately respond to the memory damage when the memory temperature is too high, such as detecting the temperatures of volatile memory, non-volatile memory and solid state drive and the temperatures, availability/health status.

In the invention, the first light-emitting device 1051, second light-emitting device 1052 and third light-emitting device 1053 in the notification module 105 of the second embodiment and the buzzer 1054 in the notification module 105 of the third embodiment can be used in an associated way.

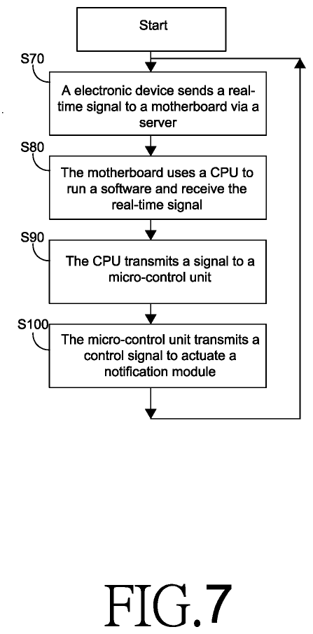

Referring to FIG. 7, which is the flowchart of temperature detection of the intelligent memory in the fourth embodiment of the invention. As shown in the figure, the steps of the method in notifying the intelligent memory in the fourth embodiment of the invention are as follows:
Step S70: A electronic device 3 sends a real-time signal 41 to a motherboard 1 via a server 4; Step S80: The motherboard 1 uses a CPU 11 to run a software 111 and receive the real-time signal 41;
Step S90: The CPU 11 transmits a signal 112 to a micro-control unit 102;
Step S100: The micro-control unit 102 transmits a control signal 113 to actuate a notification module 105.

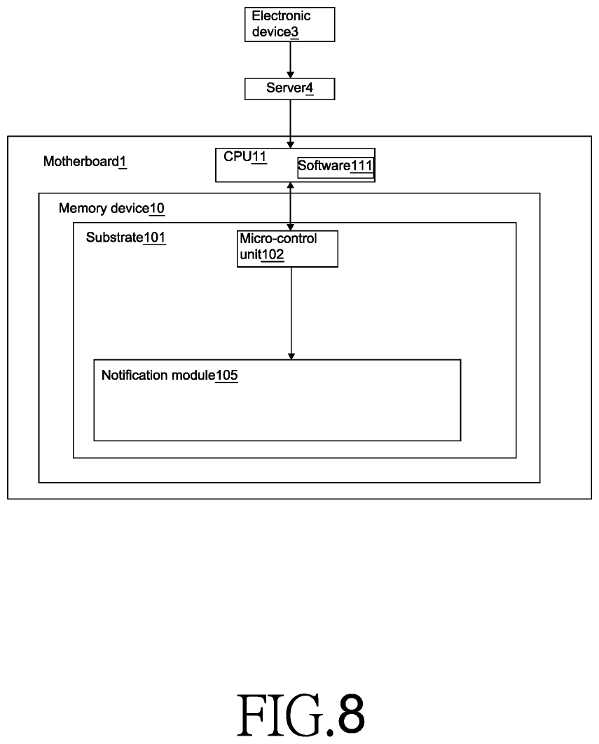

Referring to FIG. 8, which is the block diagram of intelligent memory structure in the fourth embodiment of the invention. As shown in the figure, an intelligent memory is used for a memory device 10; the memory device 10 is electrically connected to a motherboard 1 and the motherboard 1 is electrically connected to a CPU 11; the memory device 10 includes a substrate 101, a micro-control unit 102, and a notification module 105; the micro-control unit 102 and the notification module 105 are equipped on the substrate 101; the software 111 can be the communication software (for example: Facebook, Line or WeChat, etc.) or game software.

Referring to FIG. 7 again, the steps of the method notifying the intelligent memory in the fourth embodiment of the invention are described in detail below. As shown in step 70, the communication software in an electronic device 3 transmits a real-time signal 41 to a server 4; after receiving the real-time signal 41, the server 4 sends it to the motherboard 1.

As shown in step 80, the CPU 11 inside the motherboard 1 runs a software 111 to receive the real-time signal 41 from the server 4.

As shown in step 90, the CPU 11 generates a signal 112 and transmits it to the micro-control unit 102.

As shown in step 100, the micro-control unit 102 transmits a control signal 113 to activate the notification module 105.

When the motherboard 1 in the fourth embodiment of the invention receives a communication software message notification from the electronic device 3, it receives the message through the CPU 11 and transmits the signal 112 to the micro-control unit 102; the micro-control unit 102 then transmits the control signal 113 to the notification module 105 to solve the conventional problem that the memory device 10 cannot use user's communication software to obtain the real-time message.

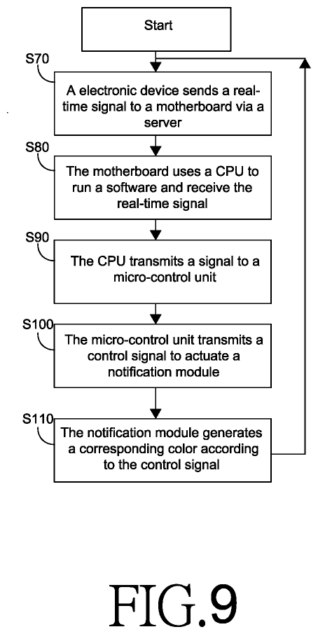

Continuing the above, refer to FIG. 9, which is the flowchart of notification method of the intelligent memory in the fifth embodiment of the invention, of which steps S70 to S100 are identical to the one in the previous embodiment and won't be iterated once again.

The fifth embodiment of the invention step is as follows:
Step S110: The notification module 105 generates a corresponding color 114 according to the control signal 113.

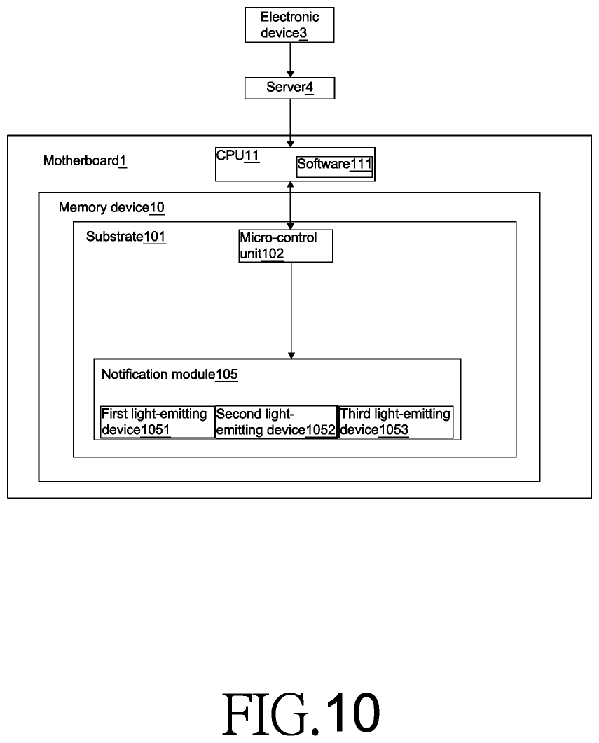

Referring to FIG. 10, which is the block diagram of intelligent memory structure in the fifth embodiment of the invention. As shown in the figure, an intelligent memory is used for the memory device 10; the memory device 10 is electrically connected to a motherboard 1; the motherboard 1 is electrically connected to a CPU 11; the memory device 10 includes a substrate 101, a micro-control unit 102 and a notification module 105; the micro-control unit 102 and the notification module 105 are equipped on the substrate 101, of which the notification module 105 includes the first light-emitting device 1051, second light-emitting device 1052, and third light-emitting device 1053.

Referring to FIG. 9 again, steps of the method notifying the intelligent memory in the fifth embodiment of the invention are described in detail below. As shown in step 110, the notification module 105 includes the first light-emitting device 1051, second light-emitting device and third light-emitting device 1053; the notification module 105 makes the first light-emitting device 1051, second light-emitting device and third light-emitting device 1053 emit light with a corresponding color 114 according to the control signal 113, of which the corresponding color 114 has been set by the user to start the corresponding program of the computer before the process starts, and the CPU 11 transmits the setting result to the micro-control unit 103 by a signal line, or the CPU 11 transmits it to the solid state drive controller through the signal line; then, the solid state drive controller transmits the signal to the micro-control unit 103 of the solid state drive.

When the motherboard 1 in the fifth embodiment of the invention receives a communication software message notification from the electronic device 3, it receives the message through the CPU 11 and transmits the signal 112 to the micro-control unit 102. The micro-control unit 102 transmits the control signal 113 is transmitted to the notification module 105, and the first light-emitting device 1051, second light-emitting device 1052 and third light-emitting device 1053 inside the notification module 105 notify the user, which can solve the problem that the conventional memory device 10 cannot be used to immediately notify message to the user's communication program.

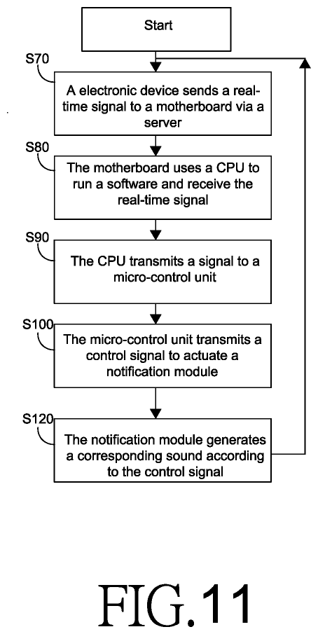

Continuing the above, refer to FIG. 11, which is the flowchart of notification method of the intelligent memory in the sixth embodiment of the invention; of which steps S70 to S100 are identical to the one stated in the fourth embodiment and won't be iterated once again.

The steps in the sixth embodiment of the invention are as follows:

Step S120: The notification module 105 generates a corresponding sound 115 according to the control signal 113.

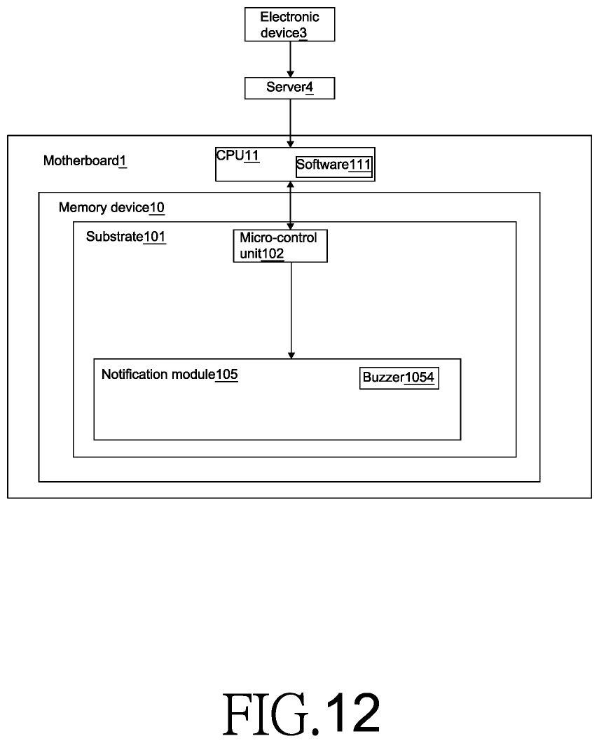

Referring to FIG. 12, which is the block diagram of intelligent memory structure in the sixth embodiment of the invention. As shown in the figure, an intelligent memory is used for the memory device 10; the memory device 10 is an electrically connected to electrically connected to a motherboard 1 and the motherboard 1 is electrically connected to a CPU 11; the memory device 10 includes a substrate 101, a micro-control unit 102, and a notification module 105. The micro-control unit 102 and the notification module 105 are equipped in the substrate 101, the notification module 105 includes the buzzer 1054.

Referring to FIG. 11 again, the steps of the method notifying the intelligent memory in the fifth embodiment of the invention are described in detail below. As shown in step 120, the notification module 105 includes the buzzer 1054; the notification module 105 enables the buzzer 1054 to use a corresponding sound 115 according to the control signal 113, of which the corresponding sound 115 has been set by the user to start the corresponding program of the computer before the process starts, and the CPU 11 transmits the setting result to the micro-control unit 103 by a signal line, or the CPU 11 transmits it to the solid state drive controller through the signal line; then, the solid state drive controller transmits the signal to the micro-control unit 103 of the solid state drive.

In the sixth embodiment of the invention, when the motherboard 1 receives a communication software message notification from the electronic device 3, it receives the message through the CPU 11 and transmits the signal 112 to the micro-control unit 102, and the micro-control unit 102 transmits the control signal 113 to the notification module 105; the buzzer 1054 inside the notification module 105 notifies the user to solve the problem that the conventional memory device 10 cannot be used to immediately notify message to the user's communication program.

In the invention, the first light-emitting device 1051, second light-emitting device 1052, and third light-emitting device 1053 of the notification module 105 in the fifth embodiment and the buzzer 1054 of the notification module 105 in the sixth embodiment can be used in an associated way.

Below, we are going to describe the practical application of an embodiment in the invention:

The setting thresholds that user uses specific computer software not the notifications of the erasable memory before running the intelligent memory is 40° C. for the first threshold 21, 50° C. for the second threshold 22, and 60° C. for the third threshold 23; the notifications of the solid state drive is 50° C. for the first threshold 21, 60° C. for the second threshold 22, and 70° C. for the third threshold 23. The first corresponding color 212 is green, second corresponding color 222 is amber, and third corresponding color 232 is red. The first sound 213 emits a sound at a slow frequency, the second sound 223 makes a sound at a normal frequency, and the third sound 233 makes a sound at a high frequency.

For a plurality of memory chips 104 of thermal sensor 103 in the memory device 10, the thermal sensor 103 can select the temperatures from a plurality of memory chips 104 to generate at least one temperature data 1041; the thermal sensor 103 generates at least one temperature data 1041 and transmit it to the micro-control unit 102. If the memory device is volatile memory or non-volatile memory, the micro-control unit 103 will determine whether the at least one temperature data 1041 exceeds 40° C., and if so, the micro-control unit 103 transmits the first control signal 211 to the notification module 105, the notification module 105 makes the first light-emitting device 1051 flashes in green light according to the first control signal 211, and the buzzer 1054 sends the first sound 213 and determine whether at least one temperature data 1041 is lower than 50° C., if it is lower than 50° C., the micro-control unit 103 transmits the first control signal 211 to the notification module 105, the first light-emitting device 1051 keeps flashing in green light, and the buzzer 1054 continues to emit the first sound 213 at a slow frequency. If it exceeds 50° C., the micro-control unit 103 will determine whether at least one temperature data 1041 is lower than 60 degrees. If it is lower than 60 degrees, the micro-control unit 103 will transmit the second control signal 221 to notification module 105, notification module 105 makes the second control signal 221 The light-emitting device 1052 flashes in orange, and the buzzer 1054 emits a second sound 223 at a normal frequency. If it exceeds 60 degrees, the micro-control unit 103 will transmit the third control signal 231 to the notification module 105. The notification module 105 uses the third control signal 231 to make The third light-emitting device 1053 flashes in red, and the buzzer 1054 emits a third sound 233 at a fast frequency. If the memory device is a solid state drive, the micro-control unit 103 determines whether at least one temperature data 1041 exceeds 50 degrees, and If yes, the micro-control unit 103 will transmit the first control signal 211 to the notification module 105, the notification module 105 will make the first light-emitting device 1051 flash green according to the first control signal 211, and the buzzer 1054 will emit the first sound 213 at a slow frequency and determine whether at least one temperature data 1041 is lower than 60° C. If it is lower than 60 degrees, the micro-control unit 103 will transmit the first control signal 211 to the notification module 105, making the first light-emitting device 1051 keep flashing in green light, and the buzzer 1054 keeps emitting the first sound 213 in a slow frequency; if it exceeds 60° C., the micro-control unit 103 will judge whether the at least one temperature data 1041 is lower than 70° C. or not. If it is lower than 70° C., the micro-control unit 103 will transmit the second control signal 221 to the notification module 105, the notification module 105 makes the second light-emitting device 1052 flash in amber color according to the second control signal 221, the buzzer 1054 emits a second sound 223 at a normal frequency; if it exceeds 70° C., the micro-control unit 103 will transmit the third control signal 231 to the notification module 105, and the notification module 105 makes the third light-emitting device 1053 flash in red color according to the third control signal 231, and the buzzer 1054 emits third sound 233 at a high frequency.

Below is the practical application description of another embodiment of the invention:

The communication software in the user's electronic device 3 transmits the real-time signal 41 to the server 4. After the server 4 receives the real-time signal 41, it sends the real-time signal 41 to the motherboard 1, and the CPU 11 inside the motherboard 1 runs the software 111 to receives the real-time signal 41 from the server 4; the CPU 11 generates the signal 112 and transmits it to the micro-control unit 102, the micro-control unit 102 transmits a control signal 113 to actuate the notification module 105, the notification module follows to the control signal 113 making the first light-emitting device 1051, second light-emitting device 1052, and third light-emitting device 1053 flash in yellow color, and the buzzer 1054 emits the corresponding sound 115 at a frequency.

In the aforesaid embodiment, the intelligent memory of the invention utilizes the thermal sensor in the memory device to sense the temperature of a plurality of memory chips with the functions of self-sensing and real-time notification, making the memory device able to self-sense the temperature of the memory device itself and real-time detect the temperature of the memory device and notify the user the detecting result through the notification module, which can solve the conventional needs of obtaining the temperatures through checking the status of computer parts; user thus can know the temperature status of the memory device and determine whether to cool down and other processing in a real-time manner, which can solve the problem that user cannot immediately respond to the memory damage when the memory temperature is too high, such as detecting the temperatures of volatile memory, non-volatile memory and solid state drive and the temperatures, availability/health status. In addition, when the communication software (Facebook, IG, or other) transmits notifications to user, it can use color or sound to notify the user.

Therefore, the invention is actually an innovative and progressive invention that can be applied in medical field, which should surely meet ROC patent application requirements patent law. We thus submit an invention patent application according to the law, expecting that the Bureau can grant the patent soon.

The statements stated above are only the preferred embodiments of the invention, which are not used to limit the claims of the invention; all the equivalent changes and modifications made according to the claims of the patent application of the invention should also belong to the claims covered in the invention.

What is claimed is:

1. A display method of an intelligent memory used for a memory device, wherein the memory device comprising a substrate, a thermal sensor, a plurality of memory chips, a micro-control unit and a notification module, and the thermal sensor, memory chips, micro-control unit and notification module are equipped on the substrate, wherein the steps of the intelligent memory temperature monitoring method comprising:
generating at least one temperature data according to the temperature of the memory chips detected by the thermal sensor;
determining whether the at least one temperature data is not less than a first threshold when the at least one temperature data is transmitted to the micro-control unit; and
transmitting a first control signal to a notification module from the micro-control unit when the at least one temperature is not less than the first threshold.

2. The display method of an intelligent memory of claim 1, wherein in said step of transmitting a first control signal to a notification module from the micro-control unit when the at least one temperature is not less than the first threshold, comparing the at least one temperature and a second threshold by the micro-control unit, and transmitting the first control signal to the notification module by the micro-control unit if the at least one temperature is less than a second threshold.

3. The display method of an intelligent memory of claim 1, wherein in said step of transmitting a first control signal to a notification module by the micro-control unit when the at least one temperature is not less than the first threshold, when the at least one temperature is not less than the second threshold, further comparing the at least one temperature data and a third threshold by the micro-control unit, and transmitting a second control signal to the notification module by the micro-control unit if the at least one temperature data is not less than a third threshold, or transmitting a third control signal to the notification module by the micro-control unit if the at least one temperature data is less than a third threshold.

4. The display method of an intelligent memory of claim 1, wherein the notification module comprising a first light-emitting device; and the first light-emitting device emits light with the first corresponding color when the notification module receives the first control signal.

5. The display method of an intelligent memory of claim 3, wherein the notification module comprising a second light-emitting device and a third light-emitting device, and the second light-emitting device emits light with the second corresponding color when the notification module receives the second control signal, and the third light-emitting device emits light with the third corresponding color when the notification module receives the third control signal.

6. The display method of an intelligent memory of claim 1, wherein the notification module comprising a buzzer, and the buzzer generates a first sound when the notification module receives the first control signal; the buzzer generates a second sound when the notification module receives the second control signal; and the buzzer generates a third sound when the notification module receives the third control signal.

7. The display method of an intelligent memory of claim 1, wherein the memory device is a volatile memory, a non-volatile memory, or a solid state drive.

8. The display method of an intelligent memory of claim 1, wherein the memory device is electrically connected to a motherboard, and a CPU transmits a control command to the memory device through the motherboard.

9. An intelligent memory comprising:
a substrate, which is equipped with a micro-control unit and a plurality of memory chips, wherein the micro-control unit is electrically connected to the memory chips;
a thermal sensor, which is deposited on the substrate and is electrically connected to the micro-control unit to detect one of the memory chips; and
a notification module, which is deposited on the substrate and is electrically connected to the micro-control unit,
wherein the micro-control unit receives at least one temperature from the thermal sensor; and the micro-control unit transmits a first control signal to the notification module when the at least one temperature is not less than a first threshold.

10. The intelligent memory of claim 9, wherein in said step of transmitting a first control signal to a notification module by the micro-control unit when the at least one temperature is not less than the first threshold, the micro-control unit determines that whether the at least one temperature is less than a second threshold, and if so, the micro-control unit transmits the first control signal to the notification module.

11. The intelligent memory of claim 9, wherein in said step of the micro-control unit transmits a first control signal to the notification module when the at least one temperature is not less than a first threshold, further comparing the at least one temperature and a third threshold by the micro-control unit when the at least one temperature is not less than the second threshold, and transmitting a second control signal to the notification module by the micro-control unit if the at least one temperature is not less than the third threshold, or the micro-control unit transmits a third control signal to the notification module by the micro-control unit if the at least one temperature is less than the third threshold.

12. The intelligent memory of claim 9, wherein the notification module comprising a first light-emitting device, and the light-emitting devices emit light with a first corresponding color when the notification module receives the first control signal.

13. The intelligent memory of claim 11, wherein the notification module comprising a second light-emitting device and a third light-emitting device; the light-emitting device emits light with a second corresponding color when the notification module receives the second control signal; and the light-emitting device emits light with a third corresponding color when the notification module receives the third control signal.

14. The intelligent memory of claim 11, wherein the notification module comprising a buzzer, and the buzzer generates a first sound when the notification module receives the first control signal, and the buzzer generates a second sound when the notification module receives the second control signal, and the buzzer generates a third sound when the notification module receives the third control signal.

15. The intelligent memory of claim 9, wherein the intelligent memory is a volatile memory, a non-volatile memory or a solid state drive.

16. The intelligent memory of claim 9, wherein the intelligent memory is electrically connected to a motherboard, and a CPU unit transmits a control command to the memory device through the motherboard.

17. A display method of an intelligent memory used for a memory device, wherein the memory device is electrically connected to a motherboard, the motherboard is electrically connected to a CPU, and the memory device comprising a substrate, a micro-control unit, and a notification module, and the micro-control unit and the notification module are equipped on the substrate, wherein the steps of the intelligent memory monitoring method comprising:
sending a real-time signal to the motherboard via a server by an electronic device, wherein the motherboard receives the real-time signal by running a software by the CPU;
transmitting a signal to the micro-control unit by the CPU; and
transmitting a control signal by the micro-control unit to activate the notification module.

18. The display method for the intelligent memory of claim 17, wherein the software is a real-time messaging software or a game software.

19. The display method for the intelligent memory of claim 17, wherein the notification module comprising a first light-emitting device, a second light-emitting device, and a third light-emitting device, and the first light-emitting device, second light-emitting device and third light-emitting device emit light with a corresponding color when the notification module receives the control signal.

20. The display method for the intelligent memory of claim 17, wherein the notification module comprising a buzzer, and the buzzer generates a corresponding sound when the notification module receives the control signal.

21. The display method for the intelligent memory of claim 17, wherein the memory device is a volatile memory, a non-volatile memory, or a solid state drive.

22. An intelligent memory, which is electrically connected to a motherboard and the motherboard is electrically connected to a CPU, the intelligent memory comprising:
a substrate, equipped with a micro-control unit; and
a notification module, which is deposited on the substrate and is electrically connected to the micro-control unit;
wherein an electronic device transmits a real-time signal to the motherboard via a server, and the motherboard receives the real-time signal by running a software by the CPU, and the CPU transmits a signal to the micro-control unit, and the micro-control unit transmits a control signal to activate the notification module.

23. The intelligent memory of claim 22, wherein the software is a real-time communication software or a game software.

24. The intelligent memory of claim 22, wherein the notification module comprising a first light-emitting device, a second light-emitting device, and a third light-emitting device, wherein the first light-emitting device, the second light-emitting device and the third light-emitting device emit lights with a corresponding color when the notification module receives the control signal.

25. The intelligent memory of claim 22, wherein the notification module comprising a buzzer; and the buzzer generates a corresponding sound when the notification module receives the control signal.

26. The intelligent memory of claim 22, wherein the intelligent memory is a volatile memory, a non-volatile memory, or a solid state drive.
